(19) United States
(12) Patent Application Publication
(10) Pub. No.: US 2025/0180782 A1
(43) Pub. Date: Jun. 5, 2025

(54) ANTI-REFLECTION FILM, POLARIZING PLATE AND DISPLAY DEVICE USING THE SAME

(71) Applicant: TOPPAN TOMOEGAWA OPTICAL FILMS CO., LTD., Tokyo (JP)

(72) Inventors: Rui INOUE, Tokyo (JP); Ryota OZAKI, Tokyo (JP)

(21) Appl. No.: 18/840,467

(22) PCT Filed: Jan. 31, 2024
(86) PCT No.: PCT/JP2024/003181

§ 371 Date: Aug. 21, 2024

(30) Foreign Application Priority Data
Feb. 2, 2023 (JP) 2023-014843

(51) Int. Cl. G02B 1/115; G02B 27/00; G02B 27/01

(52) U.S. Cl. CPC G02B 1/115; G02B 27/0018; G02B 27/0172

(57) ABSTRACT

The present invention provides an anti-reflection film capable of suppressing the occurrence of ghosts in VR goggles, and a polarizing plate and a display device using the same. The anti-reflection film is characterized in that the luminous reflectance of regular reflection light of light incident at an incidence angle of 5° is 0.3% or less, the luminous reflectance of regular reflection light of light incident at an incidence angle of 25° is 0.3% or less, and the color difference ΔE*ab value between the regular reflection light of light incident at an incidence angle of 5° and the regular reflection light of light incident at an incidence angle of 25° is 5 or less.

### TECHNICAL FIELD

The present invention relates to an anti-reflection film for use in a display device, and a polarizing plate and a display device using the same.

### BACKGROUND ART

An anti-reflection film for suppressing reflection of external light is provided in image display devices such as liquid crystal display devices and organic EL display devices. For example, Patent Documents 1 to 3 describe a configuration in which a hard coating layer, and an anti-reflection layer formed by alternately laminating a low refractive index material layer and a high refractive index material layer are provided on a transparent substrate, as an optical laminate that can make color unevenness less visible even when the viewing angle is changed.

### PRIOR ART DOCUMENT

### Patent Document

Patent Document 1: JP-A No. 2022-2903
Patent Document 2: Japanese Patent No. 6956909
Patent Document 3: International Publication WO2021/193416

### SUMMARY OF THE INVENTION

### Problems to be Solved by the Invention

In recent years, display devices called VR goggles are becoming popular as devices that allow users to experience virtual reality. VR goggles can provide a different sense of immersion from conventional display devices due to their high-definition images and the closeness between the screen and the user. Unlike conventional display devices such as televisions, and the like, VR goggles have a closed mechanism, so no external light can enter, but reflected light inside the device affects visibility. For example, light reflected on the surface of an optical member such as a lens or the like inside the device is seen by the user as a ghost, which deteriorates the visibility of the image and impairs the sense of immersion. Ghosts caused by reflected light can be suppressed by providing an anti-reflection film on the surface of the optical member, however, depending on the optical characteristics of the anti-reflection film, the reflected light may be colored, which may impair visibility even if the reflection is low. However, the characteristics of anti-reflection films suitable for VR goggles have not been fully studied until now.

Therefore, an object of the present invention is to provide an anti-reflection film capable of suppressing the occurrence of ghosts in VR goggles, and a polarizing plate and a display device using the same.

### Means for Solving the Problems

The anti-reflection film according to the present invention is one in which the luminous reflectance of regular reflection light of light incident at an incidence angle of 5° is 0.3% or less, the luminous reflectance of regular reflection light of light incident at an incidence angle of 25° is 0.3% or less, and the color difference ΔE*ab value between the regular reflection light of light incident at an incidence angle of 5° and the regular reflection light of light incident at an incidence angle of 25° is 5 or less.

The polarizing plate according to the present invention includes the above-mentioned anti-reflection film.

The display device according to the present invention includes a housing, a display panel accommodated in the housing, a lens disposed overlapping the display panel in the housing, and the above-mentioned anti-reflection film disposed overlapping the display panel and the lens.

### Effects of the Invention

According to the present invention, it is possible to provide an anti-reflection film capable of suppressing the occurrence of ghosts in VR goggles, as well as a polarizing plate and a display device using the same.

### BRIEF DESCRIPTION OF THE DRAWINGS

FIG. 1 is a cross-sectional view showing the layer structure of an anti-reflection film according to an embodiment.

FIG. 2 is a schematic view showing an example of the configuration of VR goggles.

### MODES FOR CARRYING OUT THE INVENTION

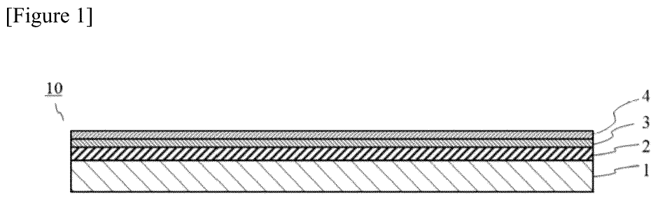

FIG. 1 is a cross-sectional view showing the layer structure of an anti-reflection film according to an embodiment.

The anti-reflection film 10 comprises a transparent film substrate 1, a hard coating layer 2 formed on one surface of the transparent film substrate 1, a high refractive index layer 3 formed on the hard coating layer 2, and a low refractive index layer 4 formed on the high refractive index layer 3.

### (Transparent Substrate)

The transparent film substrate 1 is a film that serves as the base of the anti-reflection film 10, and is made of a material that is excellent in the transparency of visible light. As the material for forming the transparent film substrate 1, transparent resins including polyolefins such as polyethylene, and polypropylene, polyesters such as polyethylene terephthalate, polybutylene terephthalate, and polyethylene naphthalate, polyacrylates such as polymethyl methacrylate, polyamides such as nylon 6, and nylon 66, polyimides, polyarylates, polycarbonates, triacetyl cellulose, polyacrylates, polyvinyl alcohol, polyvinyl chloride, cycloolefin copolymers, norbornene-containing resins, polyethersulfones, polysulfones, and the like, and inorganic glass can be used. The thickness of the transparent film substrate 1 is not particularly limited, but is preferably 10 to 200 μm.

The surface of the transparent film substrate 1 may be subjected to a surface modification treatment in order to improve adhesion to the hard coating layer 2. Examples of the surface modification treatment include an alkali treatment, a corona treatment, a plasma treatment, a sputtering treatment, an application of a surfactant, a silane coupling agent, etc., a Si vapor deposition, and the like.

### (Hard Coating Layer)

The hard coating layer 2 is a layer for imparting hardness to the anti-reflection film, and can be formed by applying a hard coating layer forming composition, which contains at least an active energy ray-curable compound, a photopolymerization initiator, and a solvent, to one side of a transparent film substrate and curing the composition. The thickness of the hard coating layer 2 is not particularly limited, but is preferably 2 to 10 μm. If the thickness of the hard coating layer 2 is less than 2 μm, the hardness of the hard coating layer 2 may be insufficient. If the thickness of the hard coating layer 2 exceeds 10 μm, it is not preferable because it is disadvantageous for thinning the anti-reflection film. However, the film thickness of the hard coating layer 2 can be appropriately set according to the surface hardness and overall thickness required for the optical film. In addition, the hard coating layer 2 may contain metal oxide fine particles for the purpose of adjusting the refractive index and imparting hardness.

The active energy ray-curable compound is a resin that is polymerized and cured by irradiation with active energy rays such as ultraviolet rays, and electron beams, and for example, a monofunctional, bifunctional, or trifunctional or higher (meth)acrylate monomer can be used. In the present specification, “(meth)acrylate” is a general term for both acrylate and methacrylate, and “(meth)acryloyl” is a general term for both acryloyl and methacryloyl.

Examples of the monofunctional (meth)acrylate compounds include 2-hydroxyethyl (meth)acrylate, 2-hydroxypropyl (meth)acrylate, 2-hydroxybutyl (meth)acrylate, n-butyl (meth)acrylate, isobutyl (meth)acrylate, t-butyl (meth)acrylate, glycidyl (meth)acrylate, acryloylmorpholine, N-vinylpyrrolidone, tetrahydrofurfuryl acrylate, cyclohexyl (meth)acrylate, 2-ethylhexyl (meth)acrylate, isobornyl (meth)acrylate, isodecyl (meth)acrylate, lauryl (meth)acrylate, tridecyl (meth)acrylate, cetyl (meth)acrylate, stearyl (meth)acrylate, benzyl (meth)acrylate, 2-ethoxyethyl (meth)acrylate, 3-methoxybutyl (meth)acrylate, ethyl carbitol (meth)acrylate, phosphate (meth)acrylate, ethylene oxide modified phosphate (meth)acrylate, phenoxy (meth)acrylate, ethylene oxide modified phenoxy (meth)acrylate, propylene oxide modified phenoxy (meth)acrylate, nonylphenol (meth)acrylate, ethylene oxide modified nonylphenol (meth)acrylate, propylene oxide modified nonylphenol (meth)acrylate, methoxydiethylene glycol (meth)acrylate, methoxypolyethylene glycol (meth)acrylate, methoxypropylene glycol (meth)acrylate, 2-(meth)acryloyloxyethyl-2-hydroxypropyl phthalate, 2-hydroxy-3-phenoxypropyl (meth)acrylate, 2-(meth)acryloyloxyethyl hydrogen phthalate, 2-(meth)acryloyloxypropyl hydrogen phthalate, 2-(meth)acryloyloxypropyl hexahydro hydrogen phthalate, 2-(meth)acryloyloxypropyl tetrahydro hydrogen phthalate, dimethylaminoethyl (meth)acrylate, trifluoroethyl (meth)acrylate, tetrafluoropropyl (meth)acrylate, hexafluoropropyl (meth)acrylate, octafluoropropyl (meth)acrylate; adamantane derivative mono(meth)acrylates such as adamantyl acrylate, having a monovalent mono(meth)acrylate derived from 2-adamantane and adamantanediol; and the like.

Examples of the bifunctional (meth)acrylate compounds include di(meth)acrylates such as ethylene glycol di(meth)acrylate, diethylene glycol di(meth)acrylate, butanediol di(meth)acrylate, hexanediol di(meth)acrylate, nonanediol di(meth)acrylate, ethoxylated hexanediol di(meth)acrylate, propoxylated hexanediol di(meth)acrylate, diethylene glycol di(meth)acrylate, polyethylene glycol di(meth)acrylate, tripropylene glycol di(meth)acrylate, polypropylene glycol di(meth)acrylate, neopentyl glycol di(meth)acrylate, ethoxylated neopentyl glycol di(meth)acrylate, tripropylene glycol di(meth)acrylate, and hydroxypivalic acid neopentyl glycol di(meth)acrylate, and the like.

Examples of the trifunctional or higher (meth)acrylate compounds include tri(meth)acrylates such as trimethylolpropane tri(meth)acrylate, ethoxylated trimethylolpropane tri(meth)acrylate, propoxylated trimethylolpropane tri(meth)acrylate, tris-2-hydroxyethyl isocyanurate tri(meth)acrylate, and glycerin tri(meth)acrylate, trifunctional (meth)acrylate compounds such as pentaerythritol tri(meth)acrylate, dipentaerythritol tri(meth)acrylate, and ditrimethylolpropane tri(meth)acrylate, tri- or more polyfunctional (meth)acrylate compounds such as pentaerythritol tetra(meth)acrylate, ditrimethylolpropane tetra(meth)acrylate, dipentaerythritol tetra(meth)acrylate, dipentaerythritol penta(meth)acrylate, ditrimethylolpropane penta(meth)acrylate, dipentaerythritol hexa(meth)acrylate, and ditrimethylolpropane hexa(meth)acrylate, as well as polyfunctional (meth)acrylate compounds in which a portion of these (meth)acrylates is substituted with an alkyl group or s-caprolactone; and the like.

In addition, as the active energy ray-curable compound, a urethane (meth)acrylate can also be used. Examples of the urethane (meth)acrylate include those obtained by reacting a polyester polyol with an isocyanate monomer or a prepolymer, and then reacting the resulting product with a (meth)acrylate monomer having a hydroxyl group.

Examples of the urethane (meth)acrylates include pentaerythritol triacrylate hexamethylene diisocyanate urethane prepolymer, dipentaerythritol pentaacrylate hexamethylene diisocyanate urethane prepolymer, pentaerythritol triacrylate toluene diisocyanate urethane prepolymer, dipentaerythritol pentaacrylate toluene diisocyanate urethane prepolymer, pentaerythritol triacrylate isophorone diisocyanate urethane prepolymer, dipentaerythritol pentaacrylate isophorone diisocyanate urethane prepolymer, and the like.

The above-mentioned active energy ray-curable compound may be used alone or in combination of two or more. In addition, the above-mentioned active energy ray-curable compound may be a monomer in the hard coating layer forming composition, or may be a partially polymerized oligomer.

As the photopolymerization initiator used in the hard coating layer forming composition, for example, 2,2-ethoxyacetophenone, 1-hydroxycyclohexyl phenyl ketone, dibenzoyl, benzoin, benzoin methyl ether, benzoin ethyl ether, p-chlorobenzophenone, p-methoxybenzophenone, Michler's ketone, acetophenone, 2-chlorothioxanthone, and the like can be used. Among these, one type may be used alone, or two or more types may be used in combination.

Examples of the solvent used in the hard coating layer forming composition include ethers such as dibutyl ether, dimethoxymethane, dimethoxyethane, diethoxyethane, propylene oxide, 1,4-dioxane, 1,3-dioxolane, 1,3,5-trioxane, tetrahydrofuran, anisole, and phenetole, ketones such as acetone, methyl ethyl ketone, diethyl ketone, dipropyl ketone, diisobutyl ketone, methyl isobutyl ketone, cyclopentanone, cyclohexanone, methylcyclohexanone, and methylcyclohexanone, esters such as ethyl formate, propyl formate, n-pentyl formate, methyl acetate, ethyl acetate, methyl propionate, ethyl propionate, n-pentyl acetate, and γ-butyrolactone, and cellosolves such as methyl cellosolve, cellosolve, butyl cellosolve, and cellosolve acetate. These may be used alone or in combination of two or more.

In addition, the hard coating layer forming composition may contain metal oxide fine particles for the purpose of adjusting the refractive index and imparting hardness. Examples of the metal oxide fine particles include zirconium oxide, titanium oxide, niobium oxide, antimony trioxide, antimony pentoxide, tin oxide, indium oxide, indium tin oxide, zinc oxide, and the like.

### (High Refractive Index Layer)

The high refractive index layer 3 is a functional layer that constitutes an anti-reflection layer together with the low refractive index layer 4, and can be formed by applying a composition for forming a high refractive index layer, which contains at least an active energy ray-curable compound, high refractive index fine particles, a photopolymerization initiator, and a solvent, onto the hard coating layer 2 and curing the composition. The active energy ray-curable compound, photopolymerization initiator, and solvent used in the composition for forming a high refractive index layer can be appropriately selected from the materials described for the hard coating layer, and used.

The refractive index of the high refractive index layer 3 is preferably in the range of 1.65 to 1.90. The refractive index of the high refractive index layer 3 can be adjusted by adding high refractive index fine particles. As the high refractive index fine particles, metal fine particles of zinc oxide (ZnO), zinc peroxide (ZnO₂), zirconium oxide (ZrO₂), titanium oxide (TiO₂), indium oxide (In₂O₃), tin(IV) oxide (SnO₂), tin(II) oxide (SnO), antimony trioxide (Sb₂O₃), cerium oxide (CeO₂), antimony oxide (SbO₂), antimony doped tin oxide (ATO), tin doped indium oxide (ITO), phosphorus doped tin oxide (PTO), and the like can be used. The average particle diameter of the high refractive index fine particles can be, for example, in the range of 1 to 100 nm. The film thickness of the high refractive index layer 3 is preferably in the range of 2 to 1000 nm.

### (Low Refractive Index Layer)

The low refractive index layer 4 can be formed by applying a composition for forming a low refractive index layer, which contains at least an active energy ray-curable compound, a photopolymerization initiator, and a solvent, onto the high refractive index layer 3 and curing the composition. The active energy ray-curable compound, photopolymerization initiator, and solvent used in the composition for forming a low refractive index layer can be appropriately selected from the materials described for the hard coating layer, and used.

The refractive index of the low refractive index layer 4 is preferably in the range of 1.20 to 1.51. The refractive index of the low refractive index layer 4 can be adjusted by adding low refractive index fine particles. As the low refractive index fine particles, lithium fluoride (LiF), magnesium fluoride (MgF₂), aluminum fluoride (AlF₃), sodium hexafluoroaluminum (Na₃AlF₆), silica particles having voids inside the particles, and the like can be used. The silica particles having voids can have the refractive index of the air (about 1) in the voids, so they are advantageous in lowering the refractive index of the low refractive index layer 4. Specifically, as the silica particles having voids, porous silica particles, hollow silica particles with a shell structure, and the like can be used. The average particle diameter of the low refractive index fine particles can be, for example, in the range of 1 to 100 nm. The film thickness of the low refractive index layer 4 is preferably in the range of 2 to 1000 nm.

In addition, the low refractive index layer 4 may contain any one of silicon oxide, fluorine-containing silane compound, fluoroalkylsilazane, fluoroalkylsilane, fluorine-containing silicon-based compound, and perfluoropolyether group-containing silane coupling agent, which impart water repellency and/or oil repellency and enhance antifouling properties.

As other additives, a leveling agent, a defoaming agent, an antioxidant, a light stabilizer, a photosensitizer, a conductive material, and the like may be added to any or all of the hard coating layer forming composition, the composition for forming a high refractive index layer, and the composition for forming a low refractive index layer, as necessary.

As an example, when zirconium oxide (refractive index: 1.76±0.02) is used as the high refractive index fine particles and hollow silica fine particles having a shell structure (refractive index: 1.29±0.02) are used as the low refractive index fine particles, by forming an anti-reflection layer in which the film thickness of the high refractive index layer 3 is within the range of 132.5 nm to 157.5 nm and the film thickness of the low refractive index layer 4 is within the range of 92.5 nm to 112.5 nm, it is possible to form an anti-reflection film 10 that satisfies the conditions described below (the luminous reflectance of the regular reflection light of light incident at an incidence angle of 5° and the luminous reflectance of the regular reflection light of light incident at an incidence angle of 25° are both 0.3% or less, and the color difference ΔE*ab between the regular reflection light of light incident at an incidence angle of 5° and the regular reflection light of light incident at an incidence angle of 25° is 5 or less). In this case, by setting the film thickness of the high refractive index layer 3 within the range of 140.0 nm to 157.5 nm and the film thickness of the low refractive index layer 4 within the range of 95.0 nm to 112.5 nm, the color difference ΔE*ab can be set to 3 or less, which is difficult to distinguish with the naked eye, and ghosts can be made less visible.

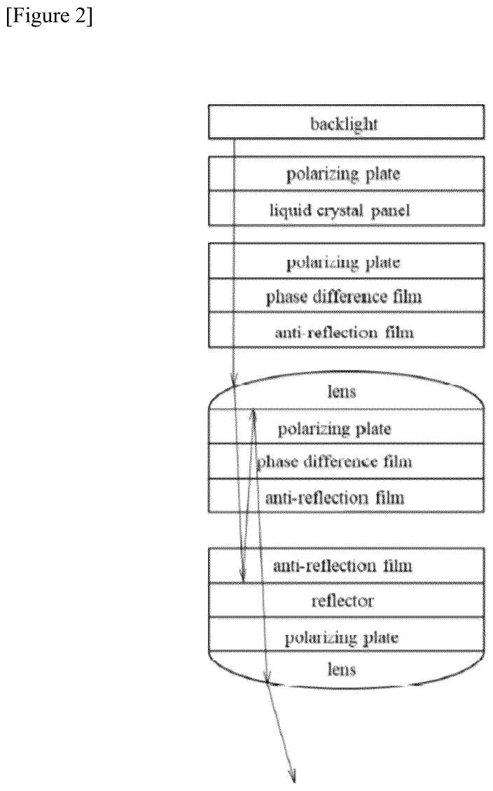

FIG. 2 is a schematic view showing a configuration example of VR goggles. The configuration shown in FIG. 2 is an example, and the combination of components used varies depending on the model, and there are, for example, a configuration in which an organic EL panel is used instead of the liquid crystal display panel shown in FIG. 2, a configuration in which a lens system consisting of one lens is used, and the like. In general, VR goggles are configured by arranging an image display panel, a lens, and an optical film such as a polarizing plate, and a phase difference film so as to overlap each other in a housing. When in use, the VR goggles are worn on the head so that each lens faces both eyes. When the VR goggles are worn, the inside of the housing is closed, and the intrusion of external light into the housing is suppressed. However, a plurality of optical members such as a lens and the like and optical films such as a polarizing plate and the like are arranged between the display panel in the housing and the user's eyes, and a portion of the light emitted from the display panel is reflected multiple times on the surfaces of these optical members and optical films.

For example, as shown by the arrow in FIG. 2, a part of the light emitted from the backlight is refracted at the lens surface, enters the reflector, and is reflected by the reflector surface toward the backlight. A part of this reflected light is reflected again by the lens surface on the backlight side, passes through the lens on the user side, and enters the user's eye. When the light reflected multiple times by the surface of the optical member enters the user's eye, it is visually recognized as a ghost, which deteriorates the visibility of the displayed image. As shown in FIG. 2, ghosts caused by reflected light can be suppressed by providing an anti-reflection film on the surface of the optical member, but depending on the optical characteristics of the anti-reflection film, the reflected light may be colored and visually recognized as a ghost, which may impair the visibility of the displayed image.

The inventors of the present application have investigated and found that regarding the optical path of light emitted from a display panel inside VR goggles, an incidence angle with respect to the optical member can be changed in the range of 5 to 25° due to refraction on the surface of optical members such as a lens and the like, and that the reflected light of light incident on the optical member at an incidence angle of 5 to 25° is visually recognized as a ghost. In addition, it has been found that in order to reduce ghosts caused by reflected light of light incident at an incidence angle of 5 to 25°, it is effective to provide an anti-reflection film 10, in which the luminous reflectance of the regular reflection light of light incident at an incidence angle of 5° and the luminous reflectance of the regular reflection light of light incident at an incidence angle of 25° are both 0.3% or less, and the color difference ΔE*ab between the regular reflection light of light incident at an incidence angle of 5° and the regular reflection light of light incident at an incidence angle of 25° is 5 or less, on the surface of the optical member.

Here, the luminous reflectance (also referred to as “average luminous reflectance”) is a value obtained by applying a light beam at an incidence angle of 5° or 25° to the outermost surface (low refractive index layer 4) of the anti-reflection film 10 with a spectrophotometer to obtain a spectral reflectance curve, and converting the obtained spectral reflectance curve to average luminous reflectance in accordance with JIS R3106, and is the Y value in the XYZ color system.

Further, the color difference ΔE*ab is a difference between two color sensations defined by the following formula using ΔL*, Δa*, and Δb*, which are differences of the coordinates L*, a*, and b* expressed in the L*a*b* color system, and is specified in JIS Z8730:2009.

$${{{{Δ E * ab = \{ ( Δ L \text{*)}}^{2} + ( Δ a \text{*)}}^{2} + ( Δ b \text{*)}}^{2} \}}^{1 / 2}$$

If either the luminous reflectance of the regular reflection light of light incident at an incidence angle of 5° or the luminous reflectance of the regular reflection light of light incident at an incidence angle of 25° exceeds 0.3%, the amount of regular reflection light increases, causing the regular reflection light to be visually recognized as a ghost, which is not preferable. Further, if the color difference ΔE*ab between the regular reflection light of light incident at an incidence angle of 5° and the regular reflection light of light incident at an incidence angle of 25° exceeds 5, even if the amount of regular reflection light is small, the reflected light is visually recognized as a ghost due to coloring, which is not preferable.

The anti-reflection film 10 according to the present embodiment has optical properties in which the luminous reflectances (Y values) of the regular reflection light of light incident at incidence angles of 5° and 25° are both 0.3% or less, and the color difference ΔE*ab of the regular reflection light of light incident at incidence angles of 5° and 25° is 5 or less. Therefore, by providing the anti-reflection film 10 according to the present embodiment on the surface of an optical member that could change the light path inside the VR goggles, it becomes possible to reduce reflected light (ghosts) inside the VR goggles and suppress coloring of the reflected light, thereby improving the visibility of the displayed image of the VR goggles.

The anti-reflection film 10 according to the present embodiment can be used as a component of a polarizing plate. Specifically, a linear polarizing plate in which the anti-reflection film 10 is bonded to one side of a linear polarizing film, or a circular polarizing plate in which a ¼ phase difference film and the anti-reflection film 10 are bonded in this order to one side of a linear polarizing film can be formed. The polarizing plate using the anti-reflection film 10 according to the present embodiment can be used by being superimposed on optical members such as a display panel, a lens, and the like accommodated inside the housing of the VR goggles, and is effective in reducing reflected light in the VR goggles and suppressing coloring of the reflected light.

### Examples

Examples of the present invention will now be described in detail.

As examples and comparative examples, an anti-reflection film having the layer structure (transparent film substrate/hard coating layer/high refractive index layer/low refractive index layer) shown in FIG. 1 was prepared. A polymethyl methacrylate (PMMA) film having a thickness of 40 μm was used as the transparent film substrate. A hard coating layer forming composition containing a ultraviolet-curable acrylic resin (pentaerythritol triacrylate (PETA)), a fluororesin, a photopolymerization initiator and a solvent was applied onto the transparent film substrate, and dried, then, the coating film was polymerized and cured by ultraviolet irradiation to form a hard coating layer having a thickness of 5.5 μm.

Next, a coating solution for forming a high refractive index layer containing an ultraviolet-curable acrylic resin (PETA), a fluororesin, zirconia (zirconium oxide) fine particles, a photopolymerization initiator and a solvent was applied onto the hard coating layer, and dried, then, the coating film was polymerized and cured by ultraviolet irradiation to form a high refractive index layer with a refractive index of 1.76. The coating amount was adjusted so that the thickness (physical film thickness) of the high refractive index layer after curing was the value shown in Table 1.

Next, a coating solution for forming a low refractive index layer containing an ultraviolet-curable acrylic resin (PETA), a fluororesin, hollow silica fine particles, a photopolymerization initiator and a solvent was applied onto the high refractive index layer, and dried, then, the coating film was polymerized and cured by ultraviolet irradiation to form a low refractive index layer with a refractive index of 1.29. The coating amount was adjusted so that the thickness (physical film thickness) of the low refractive index layer after curing was the value shown in Table 1.

### [Average Luminous Reflectance]

The spectral reflectance on the low refractive index layer surface of the anti-reflection films according to Examples 1 to 4 and Comparative Examples 1 to 7 was measured using an automatic spectrophotometer (U-4100 manufactured by Hitachi, Ltd.). In the spectral reflectance measurement, a matte blackboard was attached to the back surface of the optical laminate (the surface opposite to the surface on which the low refractive index layer was provided in the transparent film substrate) to perform an anti-reflection treatment, and measurements were performed for light incident at incidence angles of 5° and 25°. The luminous reflectances (Y values) were calculated from the obtained spectral reflectance curves in accordance with JIS R3106.

### [Color Difference]

In addition, using an anti-reflection film that had been subjected to an anti-reflection treatment in the same manner as in the measurement of the average luminous reflectance, light was irradiated respectively onto the surface of the low refractive index layer at incidence angles of 5° and 25° using a spectrophotometer (U-4100 manufactured by Hitachi, Ltd.) to measure the color coordinates L*, a* and b* of the reflected light in the L*a*b* color system, and the color difference ΔE*ab value between the regular reflection light of light incident at an incidence angle of 5° and the regular reflection light of light incident at an incidence angle of 25° was calculated according to the following formula.

$${{{{Δ E * ab = \{ ( Δ L \text{*)}}^{2} + ( Δ a \text{*)}}^{2} + ( Δ b \text{*)}}^{2} \}}^{1 / 2}$$

### [Ghost Visibility]

A commercially available VR goggle (Oculus (registered trademark) Quest2) was disassembled, the anti-reflection films provided on the image display panel and two lenses were peeled off, and the anti-reflection films according to Examples 1 to 4 and Comparative Examples 1 to 7 were attached with an optical adhesive (TD06A, manufactured by Tomoegawa Corporation), and the VR goggle was reassembled. The structure of the VR goggle used is shown in FIG. 2. The subject wore the VR goggle, and checked the visibility of ghosts with a white screen displayed.

Table 1 shows the evaluation results of the high refractive index layer thickness, the low refractive index layer thickness, the luminous reflectance Y value, the color difference ΔE*ab, and the ghost visibility for Examples 1 to 4 and Comparative Examples 1 to 7, together.

TABLE 1

| | | | | | | Compar- | Compar- | Compar- | Compar- | Compar- | Compar- | Compar- |
|---|---|---|---|---|---|---|---|---|---|---|---|---|
| | | Exam- | Exam- | Exam- | Exam- | ative | ative | ative | ative | ative | ative | ative |
| | | ple 1 | ple 2 | ple 3 | ple 4 | Example 1 | Example 2 | Example 3 | Example 4 | Example 5 | Example 6 | Example 7 |
| Thickness of high | | 132.5 | 145 | 157.5 | 147.5 | 132.5 | 160 | 140 | 160 | 130 | 142.5 | 127.5 |
| refractive index layer (nm) | | | | | | | | | | | | |
| Thickness of low refractive | | 105 | 92.5 | 97.5 | 112.5 | 107.5 | 97.5 | 92.5 | 95 | 107.5 | 90 | 107.5 |
| index layer (nm) | | | | | | | | | | | | |
| Luminous | Incidence | 0.27 | 0.12 | 0.20 | 0.28 | 0.35 | 0.24 | 0.09 | 0.31 | 0.39 | 0.14 | 0.44 |
| reflectance | angle 5° | | | | | | | | | | | |
| (Y value) | Incidence | 0.20 | 0.25 | 0.29 | 0.17 | 0.23 | 0.34 | 0.24 | 0.41 | 0.27 | 0.31 | 0.31 |
| | angle 25° | | | | | | | | | | | |

| | | | | | | | | | | | |
|---|---|---|---|---|---|---|---|---|---|---|---|
| ΔE*ab | 4.85 | 4.46 | 0.75 | 2.91 | 4.60 | 1.19 | 5.09 | 1.15 | 5.09 | 5.14 | 5.58 |
| Ghost visibility | Not no- | Not no- | Not no- | Not no- | Noticeable | Noticeable | Noticeable | Noticeable | Noticeable | Noticeable | Noticeable |
| | ticeable | ticeable | ticeable | ticeable | | | | | | | |

In all of the anti-reflection films according to Examples 1 to 4, the luminous reflectances of regular reflection light of light incident at incidence angles of 5° and 25° were 0.3% or less, and the color differences of regular reflection light of light incident at incidence angles of 5° and 25° were 5 or less, and no noticeable ghost was visible.

In the anti-reflection films according to Comparative Examples 1 to 7, the luminous reflectances of regular reflection light of light incident at the incidence angles of 5° and 25° were high or the color differences were large, so that the ghost was observed noticeably.

### INDUSTRIAL APPLICABILITY

The present invention can be used in head-mounted displays such as VR goggles (VR headsets) and the like.

### EXPLANATION OF SYMBOLS

1: Transparent film substrate
2: Hard coating layer
3: High refractive index layer
4: Low refractive index layer
10: Anti-reflection film

1. An anti-reflection film characterized in that the luminous reflectance of regular reflection light of light incident at an incidence angle of 5° is 0.3% or less, the luminous reflectance of regular reflection light of light incident at an incidence angle of 25° is 0.3% or less, and the color difference ΔE*ab value between the regular reflection light of light incident at an incidence angle of 5° and the regular reflection light of light incident at an incidence angle of 25° is 5 or less.

2. The anti-reflection film according to claim 1, characterized in that the film comprises
a transparent film substrate;
a hard coating layer formed on one surface of the transparent film substrate;
a high refractive index layer formed on the hard coating layer; and
a low refractive index layer formed on the high refractive index layer,
wherein
the refractive index of the high refractive index layer is within the range of 1.76±0.02;
the refractive index of the low refractive index layer is within the range of 1.29±0.02;
the thickness of the high refractive index layer is within the range of 132.5 nm to 157.5 nm, and
the thickness of the low refractive index layer is within the range of 92.5 nm to 112.5 nm.

3. The anti-reflection film according to claim 2, characterized in that the high refractive index layer contains metal oxide fine particles.

4. The anti-reflection film according to claim 2, characterized in that the low refractive index layer contains hollow silica fine particles.

5. A polarizing plate comprising the anti-reflection film as described in claim 1.

6. A display device comprising:
a housing;
a display panel accommodated in the housing;
a lens disposed overlapping the display panel in the housing; and
the anti-reflection film as described in claim 1, which is disposed overlapping the display panel and the lens.
